(19) United States
(12) Patent Application Publication
(10) Pub. No.: US 2025/0221186 A1
(43) Pub. Date: Jul. 3, 2025

(54) Display Device

(71) Applicant: LG Display Co., Ltd., Seoul (KR)

(72) Inventor: Joon Suk Lee, Seoul (KR)

(21) Appl. No.: 18/768,773

(22) Filed: Jul. 10, 2024

(30) Foreign Application Priority Data
Dec. 27, 2023 (KR) 10-2023-0192799

(51) Int. Cl. H10K 59/127; H10K 59/131; H10K 59/38; H10K 59/80; H10K 102/00

(52) U.S. Cl. CPC H10K 59/127; H10K 59/131; H10K 59/38; H10K 59/873; H10K 59/8792; H10K 2102/3026

(57) ABSTRACT

A display device includes a substrate with a plurality of sub-pixels on the substrate, a first structure over the substrate, an encapsulation substrate over the substrate, and a second structure below the encapsulation substrate, the second structure facing the first structure, the second structure including a plurality of stacked patterns, and a second pattern of the plurality of stacked patterns surrounds a side surface of a first pattern of the plurality of stacked patterns, the second pattern being below the first pattern, thereby preventing or at least reducing a decrease in an aperture ratio.

### CROSS-REFERENCE TO RELATED APPLICATION

This application claims the priority from Republic of Korea Patent Application No. 10-2023-0192799 filed on Dec. 27, 2023, which is hereby incorporated by reference in its entirety.

### BACKGROUND

### Field

The present disclosure relates to a display device, and more particularly, to a top emission-type display device.

### Description of Related Art

An organic light emitting display device is a self-light emitting type display device, and unlike a liquid crystal display, does not require a separate light source and can be manufactured in a light and thin form. In addition, the organic light emitting display devices are not only advantageous in terms of power consumption due to low voltage driving, but also have excellent response speed, viewing angle, and contrast ratio.

There are attempts to manufacture such organic light emitting display device into a transparent organic light emitting display device which is a transparent display device. A pixel area of the transparent organic light emitting display device is divided into a light emitting unit, which is an area where the organic light emitting diode emits light to display an image, and a transmissive unit, which is an area that transmits external light. Transmittance in the transparent organic light emitting display device is secured through a transmissive area.

### SUMMARY

An object to be achieved by the present disclosure is to provide a display device capable of improving pressing dark spots caused by internal foreign objects by maintaining a cell gap during a bonding process.

Another object to be achieved by the present disclosure is to provide a display device capable of reducing an area of a spacer for maintaining a cell gap.

Still another object to be achieved by the present disclosure is to provide a display device capable of preventing or at least reducing a decrease in aperture ratio.

Objects of the present disclosure are not limited to the above-mentioned objects, and other objects, which are not mentioned above, can be clearly understood by those skilled in the art from the following descriptions.

According to one or more embodiments of the present disclosure, a display device may include a substrate with a plurality of sub-pixels on the substrate, a first structure over the substrate, an encapsulation substrate over the substrate, and a second structure below the encapsulation substrate, the second structure facing the first structure, the second structure may include a plurality of stacked patterns, and a second pattern of the plurality of stacked patterns may surround a side surface of a first pattern of the plurality of stacked patterns, the second pattern being below the first pattern.

Other detailed matters of the embodiments of the present disclosure are included in the detailed description and the drawings.

According to the present disclosure, the first structure of the organic layer is formed, and the second structure of the stacked structure of the black matrix and the color filter is formed over the first structure, and the cell gap is uniformly maintained during the bonding process, thereby improving the pressing dark spots due to the internal foreign objects.

According to the present disclosure, the undercut structure is formed below the first structure, so it is possible to prevent or at least reduce the propagation of cracks in the protective layer generated during the bonding process, thereby improving reliability.

According to the present disclosure, it is possible to provide the effect of preventing or at least reducing the decrease in aperture ratio by reducing the areas of the first structure and the second structure.

The effects according to the present disclosure are not limited to the contents exemplified above, and more various effects are included in the present specification.

### BRIEF DESCRIPTION OF DRAWINGS

The above and other embodiments, features and other advantages of the present disclosure will be more clearly understood from the following detailed description taken in conjunction with the accompanying drawings, in which:

FIG. 1 is a block diagram for describing a display device according to one or more embodiments of the present disclosure;

FIG. 2 is a diagram schematically illustrating a configuration of a circuit of a sub-pixel according to one or more embodiments of the present disclosure;

FIG. 3 is a diagram illustrating in detail a circuit configuration of a sub-pixel according to one or more embodiments of the present disclosure;

FIG. 4A is a schematic plan view of a substrate for a pixel area of the display device according to an embodiment of the present disclosure;

FIG. 4B is a schematic plan view of an encapsulation substrate for the pixel area of the display device according to the embodiment of the present disclosure;

FIG. 5 is a cross-sectional view taken along line a-a′ of FIG. 4A according to the embodiment of the present disclosure;

FIG. 6 is a cross-sectional view of a display device according to another embodiment of the present disclosure;

FIG. 7 is a cross-sectional view of the display device according to still another embodiment of the present disclosure;

FIGS. 8A-8B, FIGS. 9A-9B, and FIGS. 10A-10B are diagrams for describing the effect of the display device according to one or more embodiments of the present disclosure;

FIG. 11 is a cross-sectional view of the display device according to still another embodiment of the present disclosure;

FIG. 12A is a schematic plan view of a substrate for a pixel area of the display device according to still another embodiment of the present disclosure;

FIG. 12B is a schematic plan view of an encapsulation substrate for the pixel area of the display device according to still another embodiment of the present disclosure; and

FIG. 13 is a cross-sectional view taken along the line b-b′ of FIG. 12A according to still another embodiment of the present disclosure.

### DETAILED DESCRIPTION

Advantages and characteristics of the present disclosure and a method of achieving the advantages and characteristics will be clear by referring to embodiments described below in detail together with the accompanying drawings. However, the present disclosure is not limited to the embodiments disclosed herein but will be implemented in various forms. The embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, embodiments of the present disclosure will be described in detail with reference to the drawings.

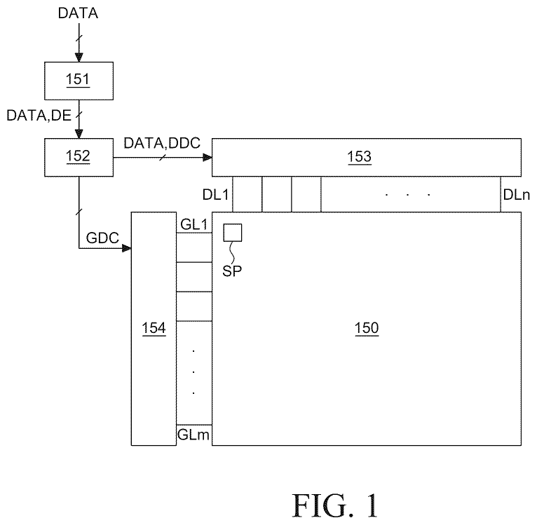

FIG. 1 is a block diagram for describing a display device according to one or more embodiments of the present disclosure.

Referring to FIG. 1, a display device according to one or more embodiments of the present disclosure may include an image processor 151, a timing controller 152, a data driver 153, a scan driver 154, and a display panel 150.

The image processor 151 may output a data enable signal DE, etc., along with a data signal DATA supplied from the outside.

In addition, for example, the image processor 151 may output one or more of a vertical synchronization signal, a horizontal synchronization signal, and a clock signal in addition to the data enable signal DE.

The timing controller 152 may receive a data signal DATA from the image processor 151 along with a driving signal that includes the data enable signal DE or a vertical synchronization signal, a horizontal synchronization signal, a clock signal, etc. In addition, the timing controller 152 may output a gate timing control signal GDC to control an operation timing of the scan driver 154 and a data timing control signal DDC to control an operation timing of the data driver 153 based on the driving signal.

The data driver 153 may sample and latch the data signal DATA supplied from the timing controller 152 in response to the data timing control signal DDC supplied from the timing controller 152, convert the sampled and latched data signal DATA into a gamma reference voltage, and output the gamma reference value. The data driver 153 may output a data signal DATA through the data lines DL1 to DLn. The data driver 153 may be formed in the form of an integrated circuit (IC).

In addition, the scan driver 154 may output a scan signal in response to the gate timing control signal GDC supplied from the timing controller 152. The scan driver 154 may output a scan signal through gate lines GL1 to GLm. The scan driver 154 may be formed in the form of the integrated circuit (IC) or may be formed in the display panel 150 in a gate-in-panel (GIP) type.

The display panel 150 may display an image in response to the data signal DATA and scan signal supplied from the data driver 153 and the scan driver 154.

The display panel 150 may include a sub-pixel SP that displays an image.

For example, the sub-pixel SP may include a red sub-pixel, a green sub-pixel, and a blue sub-pixel, or may include a white sub-pixel, a red sub-pixel, a green sub-pixel, and a blue sub-pixel. The sub-pixel SP may have one or more different emission areas according to light emitting characteristics.

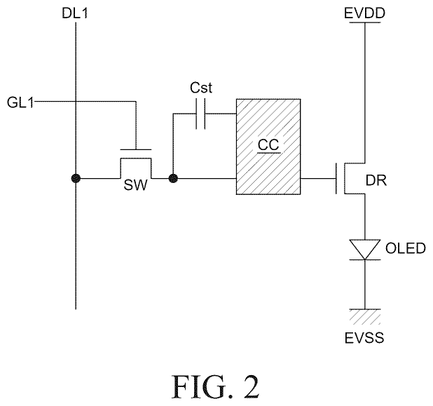

FIG. 2 is a diagram schematically illustrating a configuration of a circuit of a sub-pixel according to one or more embodiments of the present disclosure.

Referring to FIG. 2, one sub-pixel may include a switching transistor SW, a driving transistor DR, a capacitor Cst, a compensation circuit CC, and an organic light emitting diode OLED.

For example, the switching transistor SW may perform a switching operation so that a data signal supplied through a first data line DL1 is stored as a data voltage in the capacitor Cst in response to the scan signal supplied through a first gate line GL1. In addition, for example, the driving transistor DR may operate so that a driving current flows between a first power line EVDD (high potential voltage) and a second power line EVSS (low potential voltage) according to the data voltage stored in the capacitor Cst. In addition, the organic light emitting diode OLED may operate to emit light according to the driving current formed by the driving transistor DR.

The compensation circuit CC is a circuit added to the sub-pixel to compensate for a threshold voltage, etc. of the driving transistor DR. The compensation circuit CC may be configured by one or more transistors. The configuration of the compensation circuit CC varies greatly according to the external compensation method, and therefore, an example thereof is as follows.

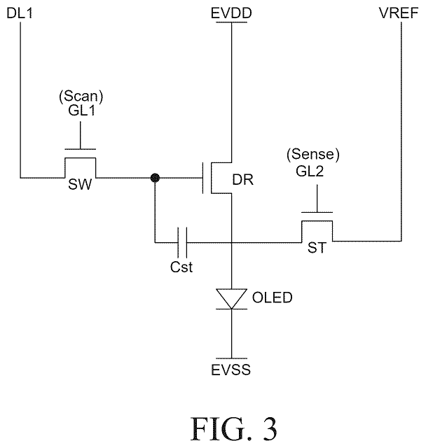

FIG. 3 is a diagram illustrating in detail a circuit configuration of a sub-pixel according to one or more embodiments of the present disclosure.

Referring to FIG. 3, for example, the compensation circuit CC may include a sensing transistor ST and a sensing line VREF (or reference line).

Here, the sensing transistor ST may be connected between a drain electrode of the driving transistor DR and a first electrode of the organic light emitting diode OLED (hereinafter referred to as a sensing node). The sensing transistor ST may operate to supply an initialization voltage (or sensing voltage) transmitted through the sensing line VREF to the sensing node of the driving transistor DR or to sense the voltage or current of the sensing node of the driving transistor DR or the sensing line VREF.

The switching transistor SW may have a source electrode or a drain electrode connected to the first data line DL1, and the remaining one of the source electrode or the drain electrode may be connected to the gate electrode of the driving transistor DR.

The driving transistor DR may have a source electrode or a drain electrode connected to the first power line EVDD, and the remaining one of the source electrode or the drain electrode may be connected to the first electrode which is an anode of the organic light emitting diode OLED.

In addition, the capacitor Cst may have a lower electrode connected to the gate electrode of the driving transistor DR and an upper electrode connected to the first electrode which is the anode electrode of the organic light emitting diode OLED. The organic light emitting diode OLED may have a first electrode connected to the remaining one of the source electrode or the drain electrode of the driving transistor DR, and a second electrode, which is a cathode electrode, connected to the second power line EVSS.

In addition, the sensing transistor ST may have a source electrode or a drain electrode connected to the sensing line VREF, and may have the remaining one of the source electrode or drain electrode connected to the first electrode of the organic light emitting diode OLED, which is the sensing node, and the remaining one of the source electrode or the drain electrode of the driving transistor DR.

The operating time of the sensing transistor ST may be similar to/same as or different from the switching transistor SW depending on the external compensation algorithm (or configuration of the compensation circuit). For example, the switching transistor SW may have a gate electrode connected to the first gate line GL1, and the sensing transistor ST may have a gate electrode connected to a second gate line GL2. In this case, a scan signal Scan may be transmitted to the first gate line GL1 and a sensing signal Sense may be transmitted to the second gate line GL2. As another example, the first gate line GL1 connected to the gate electrode of the switching transistor SW and the second gate line GL2 connected to the gate electrode of the sensing transistor ST may be connected to share in common.

The sensing line VREF may be connected to the data driver. In this case, the data driver may sense the sensing node of the sub-pixel in real time, during a non-display period of an image, or during N frames (N is an integer greater than or equal to 1) and generate sensing results.

Meanwhile, the switching transistor SW and the sensing transistor ST may be turned on at the same time. In this case, depending on the time division method of the data driver, the sensing operation through the sensing line VREF and the data output operation that outputs the data signal may be separated (divided) from each other.

In addition, the compensation target according to the sensing result may be a digital data signal, an analog data signal, gamma, etc. The compensation circuit that generates the compensation signal (or compensation voltage) based on the sensing result may be implemented inside the data driver, inside the timing controller, or as a separate circuit.

As described above, for example, in FIG. 3, a sub-pixel of a 3T (transistor) 1C (capacitor) structure, which includes the switching transistor SW, the driving transistor DR, the capacitor Cst, the organic light emitting diode OLED, and the sensing transistor ST, is described as an example, but when the compensation circuit CC is added, the sub-pixel may be configured as 3T2C, 4T2C, 5T1C, 6T2C, etc.

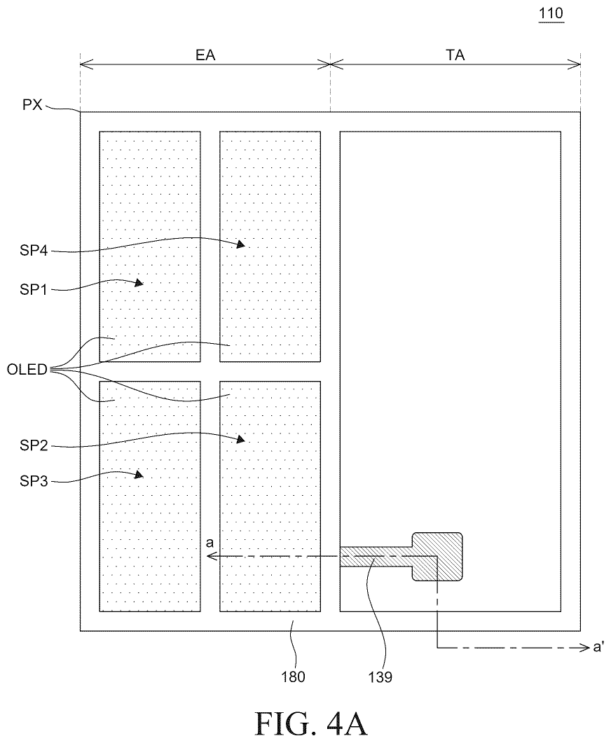

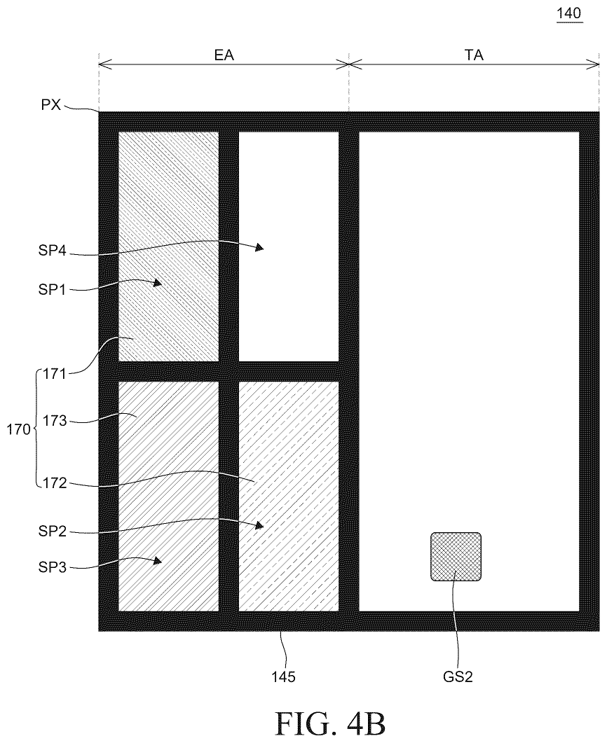

FIG. 4A is a schematic plan view of a substrate for a pixel area of the display device according to an embodiment of the present disclosure.

FIG. 4B is a schematic plan view of an encapsulation substrate for a pixel area of a display device 100 according to the embodiment of the present disclosure.

Referring to FIGS. 4A and 4B, a pixel area PX may include an emission area EA and a transmissive area TA.

The emission area EA may include a first sub-pixel SP1, a second sub-pixel SP2, a third sub-pixel SP3, and a fourth sub-pixel SP4.

The first sub-pixel SP1, the second sub-pixel SP2, the third sub-pixel SP3, and the fourth sub-pixel SP4 may each be sub-pixels that emit different colors. For example, the first sub-pixel SP1, the second sub-pixel SP2, the third sub-pixel SP3, and the fourth sub-pixel SP4 are a red sub-pixel that emits red light, a green sub-pixel that emits green light, a blue sub-pixel that emits blue light, and a white sub-pixel that emits white light, but is not limited thereto.

A common organic layer may be formed in the first sub-pixel SP1, the second sub-pixel SP2, the third sub-pixel SP3, and the fourth sub-pixel SP4 to emit white light, and a color filter 170 may be provided to distinguish colors.

In this case, the organic light emitting diode OLED is disposed in the emission area EA on the substrate 110, and each of the first sub-pixel SP1, the second sub-pixel SP2, the third sub-pixel SP3, and the fourth sub-pixel SP4 may be partitioned by a bank layer 180.

A cathode connection line 139 may be disposed in the transmissive area TA on the substrate 110. The cathode connection line 139 may extend from the emission area EA and be disposed in the transmissive area TA, and may be electrically connected to the second electrode of the organic light emitting diode OLED in the transmissive area TA.

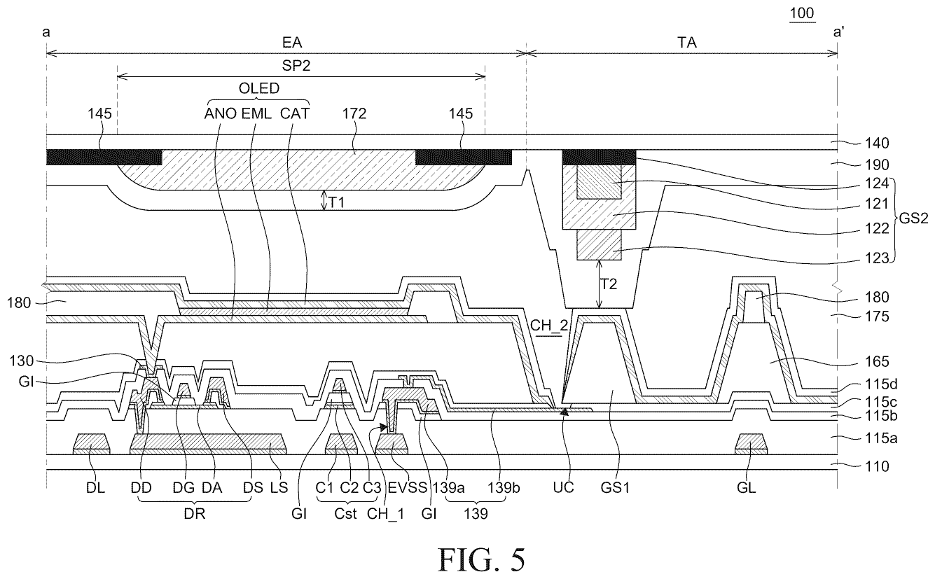

For example, the second electrode of the organic light emitting diode OLED may extend from the emission area EA to the transmissive area TA, and may be electrically connected to a top surface of the cathode connection line 139 exposed below the second structure GS2. The electrical connection between the second electrode and the cathode connection line 139 will be described in detail later with reference to FIG. 5.

In FIG. 4A, the cathode connection line 139 is illustrated as extending to the transmissive area TA in the second sub-pixel SP2 among the first to fourth sub-pixels SP1 to SP4, but is not limited thereto, and the cathode connection line 139 may extend to the transmissive area TA in one sub-pixel of the first to fourth sub-pixels SP1 to SP4 and the cathode connection line 139 may also extend to the transmissive area TA in each of the first to fourth sub-pixels SP1 to SP4.

A detailed description of the cathode connection line 139 will be described later with reference to FIG. 5.

Next, the color filter 170 may be disposed in the emission area EA on the encapsulation substrate 140, and the color filter 170 may be disposed to be surrounded by a black matrix 145. For example, a first color filter layer 171, a second color filter layer 172, and a third color filter layer 173 may be disposed in the first sub-pixel SP1, the second sub-pixel SP2, and the third sub-pixel SP3, respectively. Meanwhile, when the organic light emitting diode OLED emits white light and the fourth sub-pixel SP4 is a white sub-pixel, a separate color filter 170 may not be disposed in the fourth sub-pixel SP4, but is not limited thereto.

Meanwhile, the transmissive area TA is an area where a reflective material is not disposed, but due to design, the display device 100 may need to be disposed with a reflective material. In this case, the reflective material may be disposed to a minimum. In addition, some of various insulating layers may be removed from the transmissive area TA to secure transmittance. For example, an overcoat layer and the bank layer 180 may not be disposed in the transmissive area TA, but the present disclosure is not limited thereto.

In addition, the second structure GS2 may be disposed in the transmissive area TA. The second electrode of the organic light emitting diode OLED and the second power line EVSS may be electrically connected below the second structure GS2.

A detailed description of the second structure GS2 will be described later with reference to FIG. 5.

Meanwhile, FIGS. 4A and 4B illustrate an example of the transparent display device including the emission area EA including the first to fourth sub-pixels SP1 to SP4 and one transmissive area TA, but the present disclosure is not limited thereto.

In addition, in the display device 100 according to the embodiment of the present disclosure, the first to fourth sub-pixels SP1 to SP4 may be defined by intersecting one gate line and four data lines, but the present disclosure is not limited thereto.

FIG. 5 is a cross-sectional view taken along line a-a′ of FIG. 4A according to the embodiment of the present disclosure.

Referring to FIG. 5, a light shielding layer LS may be disposed over the substrate 110.

The substrate 110 may be a glass or plastic substrate. In the case of the plastic substrate, a polyimide-based or polycarbonate-based material may be used to provide flexibility. In particular, polyimide is widely used as the plastic substrate since it may be applied to high-temperature processes and is a coatable material.

The light shielding layer LS serves to prevent or at least reduce photocurrent from occurring in a thin film transistor by blocking external light from being incident.

The light shielding layer LS may be formed of one or more opaque conductive materials such as any one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the light shielding layer LS may be configured by a multi-layer formed of any materials selected from the group consisting of molybdenum (Mo), aluminum (Al), chromium (Cr), gold (Au), titanium (Ti), nickel (Ni), neodymium (Nd), copper (Cu), etc., or an alloy thereof. For example, the light shielding layer LS may be a double layer of molybdenum/aluminum-neodymium or molybdenum/aluminum.

The capacitor Cst may be disposed over the substrate 110. For example, the capacitor Cst may include a first capacitor electrode C1, a second capacitor electrode C2, and a third capacitor electrode C3.

The first capacitor electrode C1 of the capacitor Cst may be disposed on the same layer as the light shielding layer LS.

For example, the first capacitor electrode C1 may be formed of any one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the first capacitor electrode C1 may be configured by a multi-layer formed of any materials selected from the group consisting of molybdenum (Mo), aluminum (Al), chromium (Cr), gold (Au), titanium (Ti), nickel (Ni), neodymium (Nd), copper (Cu), etc., or an alloy thereof. For example, the first capacitor electrode C1 may be a double layer of molybdenum/aluminum-neodymium or molybdenum/aluminum.

The data line DL, the first power line (EVDD in FIG. 3), the sensing line (VREF in FIG. 3), and the second power line EVSS may be disposed on the same layer as the light shielding layer LS.

For example, the data line DL, the first power line EVDD, the sensing line VREF, and the second power line EVSS may be formed of any one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the data line DL, the first power line EVDD, the sensing line VREF, and the second power line EVSS may be configured by a multi-layer formed of any materials selected from the group consisting of molybdenum (Mo), aluminum (Al), chromium (Cr), gold (Au), titanium (Ti), nickel (Ni), neodymium (Nd), and copper (Cu), or an alloy thereof. For example, the data line DL, the first power line EVDD, the sensing line VREF, and the second power line EVSS may be a double layer of molybdenum/aluminum-neodymium or molybdenum/aluminum.

A buffer layer 115a may be disposed on the substrate 110 on which the light shielding layer LS, the data line DL, the first power line EVDD, the sensing line VREF, the first capacitor electrode C1, and the second power line EVSS are disposed. For example, the buffer layer 115a serves to protect the thin film transistor formed in a subsequent process from impurities such as alkali ions leaking from the light shielding layer LS.

For example, the buffer layer 115a may be configured by a multi-layer formed of silicon oxide (SiOx), silicon nitride (SiNx), or the silicon oxide (SiOx) and the silicon nitride (SiNx).

Meanwhile, in FIG. 5, the buffer layer 115a is illustrated as a single layer, but is not limited thereto and may be disposed as a multi-layer.

The driving transistor DR may be disposed over the buffer layer 115a.

The driving transistor DR may include a semiconductor layer DA, a gate electrode DG, a source electrode DS, and a drain electrode DD.

The driving transistor DR may overlap the organic light emitting diode OLED, but is not limited thereto.

The semiconductor layer DA of the driving transistor DR may be disposed on the buffer layer 115a.

The semiconductor layer DA may be formed of a silicon semiconductor or an oxide semiconductor. In addition, the silicon semiconductor may include amorphous silicon or crystallized polycrystalline silicon.

In addition, the semiconductor layer DA may include a drain region and a source region containing p-type or n-type impurities, and may include a channel therebetween. A lower electrode of the capacitor, for example, the second capacitor electrode C2, may also be doped with impurities to become a conductor, but is not limited thereto.

For example, the second capacitor electrode C2 of the capacitor Cst may be disposed on the same layer as the semiconductor layer DA of the driving transistor DR.

The second capacitor electrode C2 may be formed of a silicon semiconductor or an oxide semiconductor. In addition, the silicon semiconductor may include, but is not limited to, amorphous silicon or crystallized polycrystalline silicon.

The semiconductor layers of the sensing transistor ST and the switching transistor SW may be disposed on the same layer as the semiconductor layer DA of the driving transistor DR.

For example, the semiconductor layers of the sensing transistor ST and the switching transistor SW may be formed of a silicon semiconductor or an oxide semiconductor. In addition, the silicon semiconductor may include, but is not limited to, amorphous silicon or crystallized polycrystalline silicon.

A gate insulating film GI may be disposed on the semiconductor layer DA.

For example, the gate insulating film GI may be configured by silicon oxide (SiOx), silicon nitride (SiNx), or a multi-layer of the silicon oxide (SiOx) and the silicon nitride (SiNx).

In FIG. 5, the gate insulating film GI is illustrated as being patterned and disposed in a partial area, but is not limited thereto and may be disposed on the entire surface of the substrate 110.

In addition, the gate electrode DG of the driving transistor DR may be disposed at a position corresponding to a channel region of the semiconductor layer DA on the gate insulating film GI.

Although not illustrated in FIG. 5, the gate electrodes of the sensing transistor and the switching transistor may be disposed on the same layer as the gate electrode DG of the driving transistor DR. In addition, the source electrode DS and the drain electrode DD of the driving transistor DR may be disposed on the same layer as the gate electrode DG of the driving transistor DR. In addition, the source electrode and the drain electrode of the sensing transistor and the switching transistor may be disposed on the same layer as the gate electrode DG of the driving transistor DR, but are not limited thereto.

The gate electrode DG, the source electrode DS, and the drain electrode DD of the driving transistor DR, the gate electrode, the source electrode, and the drain electrode of the sensing transistor, and the gate electrode, the source electrode, and the drain electrode of the switching transistor may be formed of any one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the gate electrode DG, the source electrode DS, and the drain electrode DD may be configured by a multi-layer formed of any materials selected from the group consisting of molybdenum (Mo), aluminum (Al), chromium (Cr), gold (Au), titanium (Ti), nickel (Ni), neodymium (Nd), or copper (Cu), or an alloy thereof. For example, the gate electrode DG, the source electrode DS, and the drain electrode DD may be a double layer of molybdenum/aluminum-neodymium or molybdenum/aluminum.

The third capacitor electrode C3 of the capacitor Cst may be disposed on the same layer as the gate electrode DG of the driving transistor DR. In this case, the third capacitor electrode C3 may be formed of any one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the third capacitor electrode C3 may be configured by a multi-layer formed of any materials selected from the group consisting of molybdenum (Mo), aluminum (Al), chromium (Cr), gold (Au), titanium (Ti), nickel (Ni), neodymium (Nd), or copper (Cu), or an alloy thereof. For example, the third capacitor electrode C3 may be a double layer of molybdenum/aluminum-neodymium or molybdenum/aluminum.

A first cathode connection line 139a may be disposed on the same layer as the gate electrode DG, the source electrode DS, and drain electrode DD of the driving transistor DR, and the third capacitor electrode C3 of the capacitor Cst.

The first cathode connection line 139a may constitute the cathode connection line 139 together with a second cathode connection line 139b, but is not limited thereto.

For example, the first cathode connection line 139a may be disposed on the same layer as the gate electrode DG of the driving transistor DR. The first cathode connection line 139a may be electrically connected to the second power line EVSS through a first contact hole CH_1 in the emission area EA.

In addition, for example, the first cathode connection line 139a may be connected to a second electrode CAT through a second cathode connection line 139b in the transmissive area TA. Accordingly, the cathode connection line 139 including the first cathode connection line 139a may lower resistance while applying a low potential voltage to the second electrode CAT of the organic light emitting diode OLED.

For example, the first cathode connection line 139a may be formed of any one or more materials selected from the group consisting of molybdenum (Mo), aluminum (Al), chromium (Cr), gold (Au), titanium (Ti), nickel (Ni), neodymium (Nd), and copper (Cu), or an alloy thereof. For example, the first cathode connection line 139a may be configured by a multi-layer formed of any materials selected from the group consisting of molybdenum (Mo), aluminum (Al), chromium (Cr), gold (Au), titanium (Ti), nickel (Ni), neodymium (Nd), and copper (Cu), or an alloy thereof.

For example, the first cathode connection line 139a may be a double layer of molybdenum/aluminum-neodymium or molybdenum/aluminum.

An interlayer insulating film 115b may be disposed over the substrate 110 including the driving transistor DR and the capacitor Cst.

For example, the interlayer insulating film 115b may be configured by silicon oxide (SiOx), silicon nitride (SiNx), or a multi-layer of the silicon oxide (SiOx) and the silicon nitride (SiNx).

An anode connection line 130 may be disposed on the interlayer insulating film 115b.

The anode connection line 130 may be connected to the drain electrode DD of the driving transistor DR. The anode connection line 130 may be electrically connected to a first electrode ANO in the emission area EA.

The anode connection line 130 may be configured by a single layer or a multi-layer formed of conductive materials such as copper (Cu), aluminum (Al), molybdenum (Mo), nickel (Ni), titanium (Ti), chromium (Cr), or an alloy thereof, but is not limited thereto.

The second cathode connection line 139b may be disposed on the same layer as the anode connection line 130. The second cathode connection line 139b may be electrically connected to the first cathode connection line 139a in the emission area EA.

In addition, the second cathode connection line 139b may be electrically connected to the second electrode CAT. For example, the second cathode connection line 139b may be electrically connected to the second electrode CAT in the transmissive area TA.

In addition, for example, the second electrode CAT may extend from the emission area EA to the transmissive area TA, and may be electrically connected to an upper surface of the second cathode connection line 139b exposed below a first structure GS1 and a second structure GS2.

The second cathode connection line 139b may be formed of conductive materials such as copper (Cu), aluminum (Al), molybdenum (Mo), nickel (Ni), titanium (Ti), chromium (Cr), or an alloy thereof, but is not limited thereto.

A passivation film 115c may be disposed over the substrate 110 including the anode connection line 130 and the second cathode connection line 139b. In this case, for example, the passivation film 115c is an insulating film that protects an underlying device, and may be configured by a silicon oxide film (SiOx), a silicon nitride film (SiNx), or multi-layer of the silicon oxide film (SiOx) and the silicon nitride film (SiNx).

An overcoat layer 165 may be disposed on the passivation film 115c.

The overcoat layer 165 may be a planarization film to alleviate a step difference in the lower structure, and may be formed of organic materials such as polyimide, benzocyclobutene-based resin, or acrylate.

For example, the overcoat layer 165 may be formed by a method such as spin on glass (SOG) in which the above organic materials are coated in a liquid form and then cured.

The organic light emitting diode OLED may be disposed over the overcoat layer 165.

The organic light emitting diode OLED may include the first electrode ANO, an organic layer EML, and the second electrode CAT.

More specifically, the first electrode ANO may be disposed on the overcoat layer 165. In this case, the first electrode ANO acts as a pixel electrode and may be connected to the drain electrode DD of the driving transistor DR through the anode connection line 130 connected to the first electrode ANO.

The first electrode ANO may be formed of transparent conductive materials such as indium tin oxide (ITO), indium zinc oxide (IZO), or zinc oxide (ZnO). For example, when the display device 100 of the present disclosure has a top emission structure, the first electrode ANO may be formed of a reflective electrode. Accordingly, the first electrode ANO may further include a reflective layer. In this case, for example, the reflective layer may be formed of aluminum (Al), copper (Cu), silver (Ag), nickel (Ni), or an alloy thereof, and may be preferably formed of silver/palladium/copper alloy (APC).

In addition, the bank layer 180 that partitions the first to fourth sub-pixels SP1 to SP4 may be disposed over the substrate 110 including the first electrode ANO. For example, the bank layer 180 may be formed of organic materials such as polyimide, benzocyclobutene-based resin, or acrylate.

Although not illustrated in FIG. 5, a spacer may be disposed over the bank layer 180. The spacer may prevent or at least reduce the damage to the organic light emitting diode OLED that may be generated by bringing a fine metal mask (FMM) used when forming the organic layer EML of the organic light emitting diode OLED into a direct contact with the bank layer 180 or the second electrode CAT. The spacer may be formed of the same material as the bank layer 180, or may be formed of an insulating material different from the bank layer 180, but is not limited thereto. In addition, the spacer and the bank layer 180 may be formed integrally. As the spacer is disposed on the bank layer 180, the second electrode CAT and the organic layer EML may be disposed to cover the spacer and the bank layer 180.

For example, a first structure GS1 composed of a first organic pattern may be formed above an end of the second cathode connection line 139b.

The first structure GS1 may be disposed in the transmissive area TA and may be disposed to overlap a portion of the second cathode connection line 139b.

The first structure GS1 may be formed of the same material as the overcoat layer 165.

The first structure GS1 may be disposed in an island shape. In addition, for example, the first structure GS1 may be formed in the island shape during the process of forming a second contact hole CH_2 in the bank layer 180, the overcoat layer 165, and the passivation film 115c. The second contact hole CH_2 may be referred to as a cathode contact hole.

Meanwhile, a portion of the top surface of the second cathode connection line 139b may be exposed by the cathode contact hole CH_2.

The cathode contact hole CH_2 may expose a portion of the top surface of the second cathode connection line 139b below the first structure GS1, and may expose a portion of the top surface of the second cathode connection line 139b in an area adjacent to the first structure GS1.

An undercut UC may be formed below the first structure GS1 patterned in the island shape. For example, a side surface of the passivation film 115c below the first structure GS1 may be etched inward than the first structure GS1 to form the undercut UC.

Meanwhile, the overcoat layer 165 and the bank layer 180 may also be disposed over a gate line GL. This is because the overcoat layer 165 and the bank layer 180 over the gate line GL may also be used as additional lower structures if necessary. In this case, the maintenance of the cell gap by the first structure GS1, and the second structure GS2 which will be described later may be more effectively supplemented. In addition, the overcoat layer 165 and the bank layer 180 over the gate line GL positioned adjacent to the first structure GS1 may also serve to prevent or at least reduce the movement of the second structure GS2.

The organic layer EML in contact with the first electrode ANO may be disposed over the substrate 110. In this case, the organic layer EML may include a light emitting layer that emits light by combining electrons and holes, and may include a hole injection layer or a hole transport layer between the light emitting layer and the first electrode ANO, and an electron transport layer or an electron injection layer over the light emitting layer.

The organic layer EML may be disposed in the first to fourth sub-pixels SP1 to SP4 and may be a common organic layer that emits white light. However, the present disclosure is not limited thereto, and a red organic layer, a green organic layer, a blue organic layer, and a white organic layer may each be disposed in the first to fourth sub-pixels SP1 to SP4, respectively.

For convenience, in FIG. 5, the organic layer EML is illustrated as disposed only on the first electrode ANO exposed to the bank layer 180. However, some layers of the organic layer EML may extend to neighboring sub-pixels SP1 to SP4 and the transmissive area TA.

The second electrode CAT may be disposed on the organic layer EML. The second electrode CAT is a cathode electrode and is positioned on the entire surface of the display area, and may be formed of, for example, magnesium (Mg), calcium (Ca), aluminum (Al), silver (Ag), or an alloy thereof having a low work function. The second electrode CAT may be a transmission electrode and may be configured to be thin enough to allow light to transmit.

Meanwhile, some layers of the organic layer EML and the second electrode CAT extend to the transmissive area TA, and may be separated from some layers of the organic layer EML and the second electrode CAT on the first structure GS1 by the undercut UC. For example, the second electrode CAT may extend to the transmissive area TA and may be electrically connected to the top surface of the second cathode connection line 139b exposed by the cathode contact hole CH_2. For example, some layers of the organic layer EML separated by the undercut UC and the second electrode CAT may be stacked over the first structure GS1 in the island shape.

A protective layer 115d may be disposed on the second electrode CAT.

The protective layer 115d may be an inorganic layer, and in this case, may be configured by silicon oxide (SiOx), silicon nitride (SiNx), or a multi-layer of the silicon oxide (SiOx) and the silicon nitride (SiNx).

The protective layer 115d may extend to the transmissive area TA. For example, the protective layer 115d may extend to the transmissive area TA and may be disposed even on the second electrode CAT over the first structure GS1.

Meanwhile, although not illustrated, a capping layer may also be disposed on the organic light emitting diode OLED. The capping layer may be formed of a material with a high refractive index and high light absorption rate in order to reduce the diffuse reflection of external light.

An adhesive film 175 and the encapsulation substrate 140 may be disposed over the protective layer 115d.

For example, in the case of the top emission manner, the adhesive film 175 may be bonded to the encapsulation substrate 140 while being disposed over the substrate 110 on which the organic light emitting diode OLED is disposed.

In addition, the black matrix 145 may be disposed on one surface of the encapsulation substrate 140 facing the substrate 110. Here, for convenience of description, one surface of the encapsulation substrate 140 facing the substrate 110 will be referred to as the top surface.

For example, the black matrix 145 may be disposed to be spaced apart from the black matrices 145 of other sub-pixels SP1 to SP4 disposed adjacently, and may have an opening.

The color filter 170 may be disposed on the opening. The color filter 170 is a light conversion member, and may convert light emitted from the organic light emitting diode OLED into light of various colors. For example, the color filter 170 may be disposed in the first sub-pixel SP1, the second sub-pixel SP2, and the third sub-pixel SP3 in the emission area EA, and may be disposed to overlap a portion of the top surface of the black matrix 145. For example, the color filter 170 may include a first color filter layer (171 in FIG. 4B), a second color filter layer 172, and a third color filter layer (173 in FIG. 4B).

The first color filter layer 171 may be disposed in the first sub-pixel SP1. For example, the first color filter layer 171 may be a red color filter layer. Accordingly, the light emitted from the organic light emitting diode OLED may be red light as it transmits the first color filter layer 171 disposed in the first sub-pixel SP1.

The second color filter layer 172 may be disposed in the second sub-pixel SP2. For example, the second color filter layer 172 may be a green color filter layer. Accordingly, the light emitted from the organic light emitting diode OLED may be green light as it transmits the second color filter layer 172 disposed in the second sub-pixel SP2.

The third color filter layer 173 may be disposed in the third sub-pixel SP3. For example, the third color filter layer 173 may be a blue color filter layer. Accordingly, the light emitted from the organic light emitting diode OLED may be blue light as it transmits the third color filter layer 173 disposed in the third sub-pixel SP3.

An insulating layer 190 may be disposed below the encapsulation substrate 140 including the color filter 170. Here, the insulating layer 190 may be the overcoat layer or the planarization film, so the encapsulation substrate 140 may be planarized.

A thickness of the insulating layer 190 in the transmissive area TA and a thickness of the insulating layer 190 in the emission area EA may be different. For example, the insulating layer 190 may be formed using a halftone mask. Accordingly, the insulating layer 190 may be formed to have a difference in thickness depending on the area. However, the present disclosure is not limited thereto.

In this case, in the emission area EA, the insulating layer 190 may have a first thickness T1, and in the transmissive area TA, the insulating layer 190 may have a second thickness T2 thicker than the first thickness T1, but is not limited thereto.

Meanwhile, the insulating layer 190 may be disposed between the first structure GS1 and the second structure GS2 in the transmissive area TA. In this case, the second thickness T2 of the insulating layer 190 in the transmissive area TA may correspond to a gap between the top surface of the protective layer 115d on the first structure GS1 and the bottom surface of the second structure GS2.

Meanwhile, the second structure GS2 including a plurality of stacked patterns may be disposed below the encapsulation substrate 140 facing the first structure GS1.

The second structure GS2 may be disposed in the transmissive area TA and may be disposed to overlap the first structure GS1.

A planar shape of the second structure GS2 may have a circular or square shape, but is not limited thereto.

For example, the second structure GS2 may include a first pattern 121, a second pattern 122, a third pattern 123, and a fourth pattern 124 disposed on the bottom surface of the encapsulation substrate 140. However, the present disclosure is not limited thereto, and the number of patterns included in the second structure GS2 may vary.

For example, the first pattern 121 may be disposed below the encapsulation substrate 140.

For example, the first pattern 121 may be formed in the same process as the first color filter layer 171 and may be formed of the same material as the first color filter layer 171, and may be formed to have substantially the same thickness as the first color filter layer 171, but is not limited thereto.

The first pattern 121 may have, for example, a square shape on a plane.

Meanwhile, FIG. 5 illustrates that the side surface of the first pattern 121 is illustrated as being perpendicular to the top and bottom surfaces, and thus, the shape of the first pattern 121 is rectangular. However, the present disclosure is not limited thereto, and the cross section of the first pattern 121 may have a positive taper shape or an inverse taper shape.

The second pattern 122 may be disposed below the first pattern 121.

For example, the second pattern 122 may be formed in the same process as the second color filter layer 172 and may be formed of the same material as the second color filter layer 172, and may be formed to have substantially the same thickness as the second color filter layer 172, but is not limited thereto.

An area of the second pattern 122 may be larger than that of the first pattern 121 and that of the third pattern 123, and a width of the second pattern 122 may be larger than that of the first pattern 121 and that of the third pattern 123. In this case, the area of the first pattern 121, the area of the second pattern 122, and the area of the third pattern 123 may refer to an area where each of the first pattern 121, the second pattern 122, and the third pattern 123 overlaps the encapsulation substrate 140, respectively.

The second pattern 122 may have a square shape on a plane. Meanwhile, in FIG. 5, the side surface of the second pattern 122 is illustrated as being perpendicular to the top and bottom surfaces, but is not limited thereto, and the cross section of the second pattern 122 may have a positive taper shape or an inverse taper shape.

Meanwhile, one pattern of the plurality of patterns constituting the second structure GS2 may be disposed on the other pattern and surround a side surface of the other pattern. For example, the second pattern 122 may be disposed on the first pattern 121 and surround the side surface of the first pattern 121. Meanwhile, the difference between the width of the second pattern 122 and the width of the first pattern 121 may correspond to a process margin. The third pattern 123 may be disposed below the second pattern 122.

For example, the third pattern 123 may be formed in the same process as the third color filter layer 173 and may be formed of the same material as the third color filter layer 173, and may be formed to have substantially the same thickness as the third color filter layer 173, but is not limited thereto.

The area of the third pattern 123 and the area of the first pattern 121 may be smaller than the area of the second pattern 122. The width of the third pattern 123 and the width of the first pattern 121 may be smaller than the width of the second pattern 122.

The third pattern 123 may have a square shape on a plane. Meanwhile, in FIG. 5, the side surface of the third pattern 123 is illustrated as being perpendicular to the top and bottom surfaces, but is not limited thereto, and the cross section of the third pattern 123 may have a positive taper shape or an inverse taper shape.

Meanwhile, the difference between the width of the third pattern 123 and the width of the second pattern 122 may correspond to a process margin. In addition, the width of the third pattern 123 and the width of the first pattern 121 may be the same, but are not limited thereto.

Meanwhile, a fourth pattern 124 may be further disposed between the encapsulation substrate 140 and the first pattern 121. For example, the fourth pattern 124 may be formed during the same process as the black matrix 145 and may be made of the same material as the black matrix 145, but is not limited thereto.

An area of the fourth pattern 124 may be larger than that of the first pattern 121 and that of the third pattern 123, and a width of the fourth pattern 124 may be larger than that of the first pattern 121 and that of the third pattern 123.

The fourth pattern 124 may have a square shape on a plane. Meanwhile, in FIG. 5, the side surface of the fourth pattern 124 is illustrated as being perpendicular to the top and bottom surfaces, but is not limited thereto, and the cross section of the fourth pattern 124 may have a positive taper shape or an inverse taper shape.

Meanwhile, the difference between the width of the fourth pattern 124 and the width of the first pattern 121 may correspond to a process margin. In addition, the width of the fourth pattern 124 and the width of the second pattern 122 may be the same, but are not limited thereto.

In the above, the case where the first pattern 121, the second pattern 122, and the third pattern 123 are sequentially stacked below the fourth pattern 124 to form the second structure GS2 has been described as an example, but the present disclosure is not limited to the stacking order of the plurality of patterns.

Meanwhile, the encapsulation substrate 140 may be manufactured separately from the substrate 110 and bonded to the substrate 110 on which the adhesive film 175 is disposed. In this case, the encapsulation substrate 140 may be bonded to the substrate 110 while the second structure GS2, the color filter 170, the black matrix 145, and the insulating layer 190 are disposed. For example, in the state before being bonded, the second structure GS2, the color filter 170, the black matrix 145, and the insulating layer 190 are disposed on the encapsulation substrate 140, and the second structure GS2 may be in a state in which the fourth pattern 124, the first pattern 121, the second pattern 122, and the third pattern 123 are sequentially stacked. Thereafter, the encapsulation substrate 140 may be bonded to the substrate 110 in an overturned state. Accordingly, the color filter 170, the black matrix 145, the second structure GS2, and the insulating layer 190 may be disposed below the encapsulation substrate 140, and the second pattern 122, the first pattern 121, and the fourth pattern 124 in the plurality of patterns constituting the second structure GS2 may be sequentially disposed over the third pattern 123 as illustrated in FIG. 5, but are not limited thereto.

As such, in the display device 100 according to the embodiment of the present disclosure, the first structure GS1 may be formed over the end of the cathode connection line 139, and the second structure GS2 may be formed over the first structure GS1, thereby uniformly maintaining the cell gap during the bonding process of the substrate 110 and the encapsulation substrate 140. As a result, it is possible to improve the pressing dark spots caused by internal foreign objects.

In addition, the undercut UC structure is formed below the first structure GS1, so even if cracks occur in the protective layer 115d over the first structure GS1 due to the pressure during the bonding process, the undercut UC may prevent or at least reduce cracks from propagating to peripheral sub-pixels SP1 to SP4. As a result, it is possible to improve reliability.

In particular, as the first structure GS1 of the present disclosure is disposed over the end of the cathode connection line 139 in the transmissive area TA where there is almost no circuit configuration, the impact of cracks on the protective layer 115d may be minimized, thereby being advantageous for the reliability. The cathode connection line 139 may be disposed to extend to the transmissive area TA.

Meanwhile, the display device 100 may be implemented in a top emission or bottom emission manner. For example, in the case of the top emission manner, the adhesive film 175 may be bonded to the encapsulation substrate 140 while being disposed over the substrate 110 on which the organic light emitting diode OLED is disposed.

It is important to uniformly maintain the cell gap during the bonding process of the substrate 110 and the encapsulation substrate 140. As a distance between a dam and the adhesive film 175 increases, a large amount of pressing dark spots is generated due to the sagging of the substrate 110 and the warping of the protective layer 115d. For example, when there is no structure to maintain the cell gap, the pressing dark spots may occur due to the low cell gap. In addition, the pressing dark spots may occur due to foreign objects generated inside the display panel during the bonding process.

Accordingly, in the display device 100 according to the embodiment of the present disclosure, the first structure GS1 may be formed above the end of the cathode connection line 139, and the second structure GS2 may be formed below the encapsulation substrate 140 facing the first structure GS1. Accordingly, when bonding the substrate 110 and the encapsulation substrate 140, the second structure GS2 may be disposed over the first structure GS1. In other words, the cell gap may be uniformly maintained by the first structure GS1 and the second structure GS2, and the pressing dark spots caused by the internal foreign objects may be improved.

In addition, in the display device 100 according to the embodiment of the present disclosure, the insulating layer 190 has different thicknesses in the transmissive area TA and the emission area EA. For example, the insulating layer 190 may be disposed between the first structure GS1 and the second structure GS2 in the transmissive area TA, and the second thickness T2 of the insulating layer 190 in the transmissive area TA may be thicker than the first thickness T1 in the emission area EA. Accordingly, even if the gap between the first structure GS1 and the second structure GS2 is large, the thickness of the insulating layer 190 in the transmissive area TA may increase to fill the gap between the first structure GS1 and the second structure GS2. Accordingly, the insulating layer 190 may uniformly maintain the cell gap and improve the pressing dark spots caused by the internal foreign objects.

Meanwhile, the second structure GS2 disposed over the cathode contact area is configured by a plurality of patterns. In this case, the plurality of patterns is disposed taking a process margin into consideration. Accordingly, the area of the pattern disposed over the plurality of patterns may be larger than the area of the pattern disposed below the plurality of patterns in consideration of the process margin. Accordingly, the cross-sectional shape of the second structure GS2 has an area that increases toward the upper pattern, like an inverted pyramid shape. However, as the number of stacks of patterns constituting the second structure GS2 increases, the area of the top layer of the second structure GS2 gradually increases, so a problem may occur in which the area of the second structure GS2 increases and the aperture ratio of the transmissive area TA decreases.

Accordingly, in the display device 100 according to the embodiment of the present disclosure, one pattern of the plurality of patterns constituting the second structure GS2 may be disposed to have a larger area than the other pattern disposed over them, and thus, may be disposed to surround the side surface of the other pattern. For example, in the second structure GS2 in which the fourth pattern 124, the first pattern 121, the second pattern 122, and the third pattern 123 are stacked in that order, the area of the second pattern 122 may be disposed larger than the area of the first pattern 121. In this case, the difference between the area of the second pattern 122 and the area of the first pattern 121 may correspond to the process margin. Thereafter, the third pattern 123, which is smaller than the area of the second pattern 122, may be disposed below the second pattern 122. Therefore, by repeating the increase and decrease in area when the plurality of patterns is stacked in the second structure GS2, the total area of the second structure GS2 may be determined by considering only the area of the first pattern 121 having the minimum area of the second structure GS2 and the process margin for forming the plurality of patterns. For example, the overlapping area of the second structure GS2 with the encapsulation substrate 140 may be the same as the overlapping area of the second pattern 122 with the encapsulation substrate 140, and the second pattern 122 may correspond to the area of the first pattern 121 having the minimum area among the second structures GS2, and the area considering the process margin. Therefore, even if the number of patterns constituting the second structure GS2 increases, the area of the second structure GS2 may be maintained the same as the area of the second pattern 122, and the problem of decreasing the aperture ratio of the transmissive area TA may be improved.

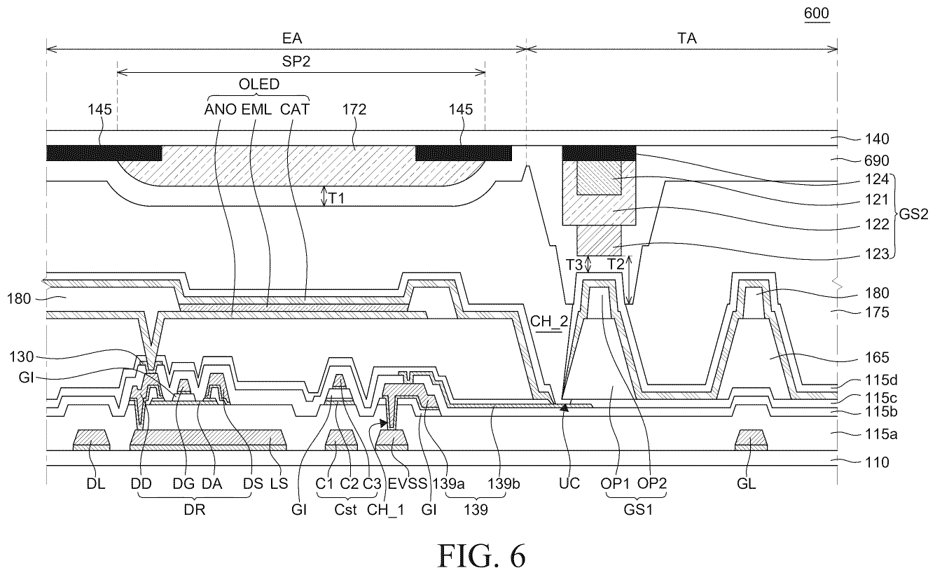

FIG. 6 is a cross-sectional view of a display device according to another embodiment of the present disclosure.

A display device 600 of FIG. 6 is different from the display device 100 of FIGS. 1 to 5 described above only in the first structure GS1 and an insulating layer 690, and other components are substantially the same, and therefore, redundant descriptions thereof will be omitted. The same reference numerals will be used for the same components. Hereinafter, descriptions of the same reference numerals may refer to FIGS. 1 to 5.

Referring to FIG. 6, the first structure GS1 may be disposed in the transmissive area TA.

The first structure GS1 may include a first organic pattern OP1 and a second organic pattern OP2.

The first organic pattern OP1 may be formed of the same material as the overcoat layer 165.

The undercut UC may be formed below the first organic pattern OP1 in the first structure GS1.

The second organic pattern OP2 may be disposed over the first organic pattern OP1. The second organic pattern OP2 may be formed of the same material as the bank layer 180.

For example, the area of the bottom surface of the second organic pattern OP2 may be smaller than the area of the top surface of the first organic pattern OP1. Accordingly, the second organic pattern OP2 may be disposed to overlap a portion of the first organic pattern OP1.

Some layers of the organic layer EML separated by the undercut UC and the second electrode CAT may be stacked over the first structure GS1. For example, some layers of the organic layer EML may cover the top and side surfaces of the second organic pattern OP2 in the first structure GS1, and cover the top surface of the first organic pattern OP1 and the side surface of the first organic pattern OP1 exposed by the second organic pattern OP2.

An insulating layer 690 may be disposed below the encapsulation substrate 140 including the color filter 170.

The insulating layer 690 may be disposed between the first structure GS1 and the second structure GS2 in the transmissive area TA. In this case, the insulating layer 690 in the transmissive area TA may have a concave groove. The insulating layer 690 may have a concave groove in the direction of the encapsulation substrate 140 in the area overlapping the second structure GS2. For example, the bottom surface of the insulating layer 690 is disposed to correspond to the top surface of the first structure GS1, and may have a concave groove to surround the top surface and the side surface of the second organic pattern OP2 in the first structure GS1.

The thickness of the insulating layer 690 in the transmissive area TA may not all be the same. For example, the thickness of the insulating layer 690 in the area overlapping the second organic pattern OP2 may be different from the thickness of the insulating layer 690 in the area not overlapping the second organic pattern OP2. For example, in the area that does not overlap the second organic pattern OP2 in the transmissive area TA, the insulating layer 690 may have a second thickness T2, and in the area that overlaps the second organic pattern OP2, the insulating layer 690 may have a third thickness T3 that is thinner than the second thickness T2. In this case, the third thickness T3 may correspond to the gap between the top surface of the second organic pattern OP2 and the bottom surface of the second structure GS2.

Meanwhile, in the emission area EA, the insulating layer 690 may have the first thickness T1 that is thinner than the second thickness T2. In this case, the first thickness T1 may be the same as the third thickness T3, but is not limited thereto.

In the display device 600 according to another embodiment of the present disclosure, the first structure GS1 may be formed above the end of the cathode connection line 139, and the second structure GS2 may be formed below the encapsulation substrate 140 facing the first structure GS1, thereby uniformly maintaining the cell gap. As a result, it is possible to improve the pressing dark spots caused by internal foreign objects.

In the display device 600 according to another embodiment of the present disclosure, the insulating layer 690 may have different thicknesses in the transmissive area TA and the emission area EA. As a result, by increasing the thickness of the insulating layer 690 in the transmissive area TA, it is possible to uniformly maintain the cell gap and improve the pressing dark spots caused by internal foreign objects.

In the display device 600 according to another embodiment of the present disclosure, the area of the plurality of patterns constituting the second structure GS2 may be stacked so that the area repeatedly increases and decreases. Therefore, even if the number of patterns constituting the second structure GS2 increases, the total area of the second structure GS2 may be kept constant and the problem of decreasing the aperture ratio of the transmissive area TA may be improved.

In the display device 600 according to another embodiment of the present disclosure, the insulating layer 690 may have a concave groove corresponding to the top surface of the second organic pattern OP2 in the area overlapping the second structure GS2, and may be disposed to surround the top and side surfaces of the second organic pattern OP2. In this way, the concave groove of the insulating layer 690 is disposed to surround a portion of the second structure GS2, thereby preventing or at least reducing the first structure GS1 from flowing. For example, when bonding the substrate 110 and the encapsulation substrate 140, the dam and the adhesive film 175 are applied in a vacuum state, the dam is cured, and then heat curing of the adhesive film 175 is performed under atmospheric pressure. In this case, the fill material of the adhesive film 175 moves from a viscosity state to an uncured state, so the change in the bonded state, such as micro-distortion, may occur between the substrate 110 and the encapsulation substrate 140 due to the change in pressure. In this case, the concave groove of the insulating layer 690 is disposed to surround a portion of the second structure GS2, thereby preventing or at least reducing the first structure GS1 from flowing.

Meanwhile, as described above, the overcoat layer 165 and the bank layer 180 may also be disposed over the gate line GL. This is because the overcoat layer 165 and the bank layer 180 over the gate line GL may also be used as additional lower structures if necessary. In this case, the maintenance of the cell gap by the first structure GS1, and the second structure GS2 which will be described later may be more effectively supplemented. In addition, the overcoat layer 165 and the bank layer 180 over the gate line GL positioned adjacent to the first structure GS1 may serve to prevent or at least reduce the movement of the second structure GS2.

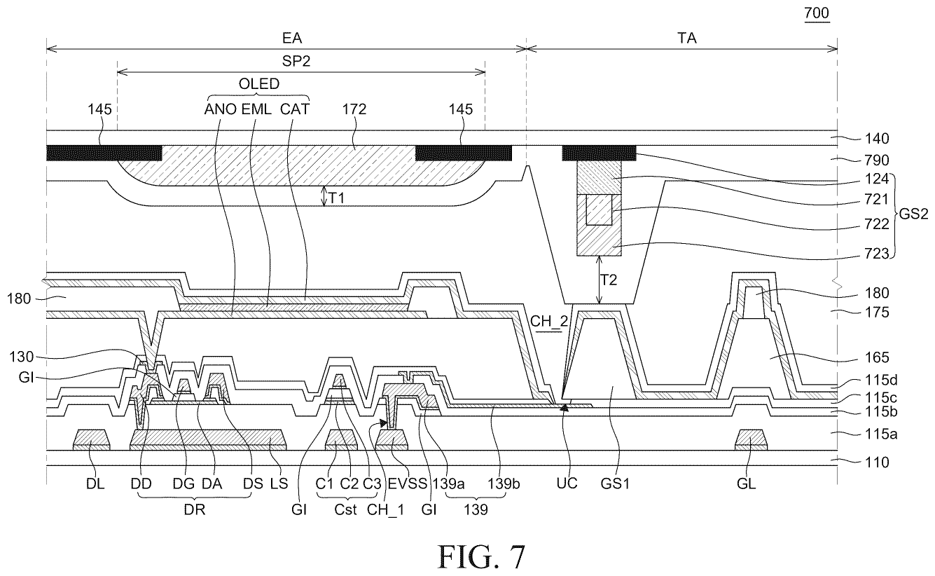

FIG. 7 is a cross-sectional view of the display device according to still another embodiment of the present disclosure.

A display device 700 of FIG. 7 is different from the display device 100 of FIGS. 1 to 5 described above only in the second structure GS2 and an insulating layer 790, and other components are substantially the same, and therefore, redundant descriptions thereof will be omitted. The same reference numerals will be used for the same components. Hereinafter, descriptions of the same reference numerals may refer to FIGS. 1 to 5.

Referring to FIG. 7, the second structure GS2 may be disposed in the transmissive area TA.

The second structure GS2 may include a first pattern 721, a second pattern 722, a third pattern 723, and a fourth pattern 124.

The fourth pattern 124 may be disposed below the encapsulation substrate 140, and the first pattern 721 may be disposed below the fourth pattern 124.

The overlapping area of the first pattern 721 with the encapsulation substrate 140 may be smaller than the overlapping area of the fourth pattern 124 with the encapsulation substrate 140. Meanwhile, the difference between the width of the fourth pattern 124 and the width of the first pattern 721 may correspond to the process margin.

The second pattern 722 may be disposed below the first pattern 721.

The overlapping area of the second pattern 722 with the encapsulation substrate 140 may be smaller than the overlapping area of the first pattern 721 with the encapsulation substrate 140. Meanwhile, the difference between the width of the first pattern 721 and the width of the second pattern 722 may correspond to the process margin.

The third pattern 723 may be disposed below the second pattern 722.

The overlapping area of the third pattern 723 with the encapsulation substrate 140 may be larger than the overlapping area of the second pattern 722 with the encapsulation substrate 140. Accordingly, the third pattern 723 may be disposed to surround the side surface of the second pattern 722. For example, a width of the first pattern 721 and a width of the third pattern 723 may be larger than a width of the second pattern 722. Therefore, the third pattern 723 and the first pattern 721 may be disposed to contact each other on an outside of the second pattern 722, and the first pattern 721 and the third pattern 723 may be disposed to surround the second pattern 722.

Meanwhile, the difference between the width of the second pattern 722 and the width of the third pattern 723 may correspond to the process margin, and the third pattern 723 may have the same width as the first pattern 721, and is not limited thereto.

An insulating layer 790 may be disposed below the encapsulation substrate 140 including the color filter 170. The insulating layer 790 may be disposed between the first structure GS1 and the second structure GS2 in the transmissive area TA.

In the display device 700 according to still another embodiment of the present disclosure, the first structure GS1 may be formed above the end of the cathode connection line 139, and the second structure GS2 may be formed below the encapsulation substrate 140 facing the first structure GS1, thereby uniformly maintaining the cell gap. As a result, it is possible to improve the pressing dark spots caused by internal foreign objects.

In addition, in the display device 700 according to still another embodiment of the present disclosure, the insulating layer 790 may have different thicknesses in the transmissive area TA and the emission area EA. For example, by increasing the thickness of the insulating layer 790 in the transmissive area TA, it is possible to uniformly maintain the cell gap and improve the pressing dark spots caused by internal foreign objects.

In the display device 700 according to still another embodiment of the present disclosure, the fourth pattern 124 and the first pattern 721 may be disposed below the encapsulation substrate 140, and the second pattern 722 having a smaller area than the first pattern 721 may be disposed below the first pattern 721. In addition, the third pattern 723 having an area larger than the second pattern 722 may be disposed below the second pattern 722 to surround the side surface of the second pattern 722. Therefore, even if the number of patterns constituting the second structure GS2 increases, the total area of the second structure GS2 may be kept constant and the problem of decreasing the aperture ratio of the transmissive area TA may be improved.

Meanwhile, as described above, the overcoat layer 165 and the bank layer 180 may also be disposed over the gate line GL. This is because the overcoat layer 165 and the bank layer 180 over the gate line GL may also be used as additional lower structures if necessary. In this case, the maintenance of the cell gap by the first structure GS1, and the second structure GS2 which will be described later may be more effectively supplemented. In addition, the overcoat layer 165 and the bank layer 180 over the gate line GL positioned adjacent to the first structure GS1 may serve to prevent or at least reduce the movement of the second structure GS2.

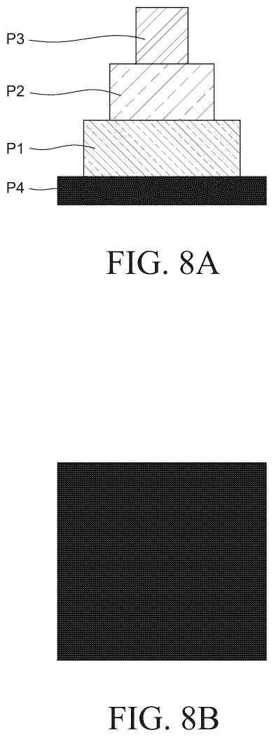

FIGS. 8A-8B, FIGS. 9A-9B, and FIGS. 10A-10B are diagrams for describing the effect of the display device according to one or more embodiments of the present disclosure.

FIG. 8A is a cross-sectional view of the second structure according to Comparative Embodiments, and FIG. 8B is a plan view of the second structure according to Comparative Embodiments.

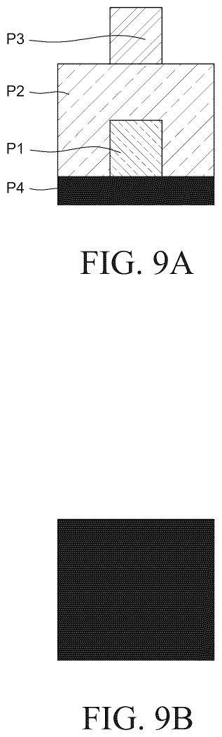

FIG. 9A is a cross-sectional view of the second structure GS2 according to Embodiment 1, and FIG. 9B is a plan view of the second structure GS2 according to Embodiment 1. Embodiment 1 is an embodiment where the second structures GS2 according to the display device 500 of FIG. 5 and the display device 600 of FIG. 6 are provided.

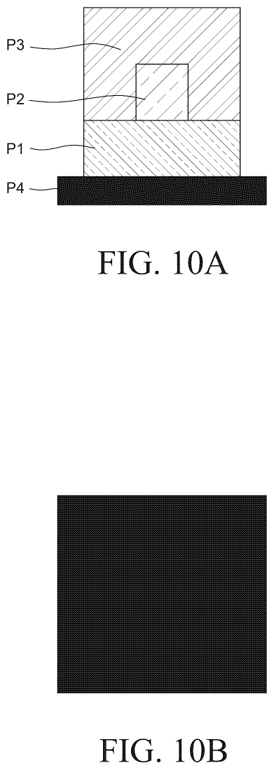

FIG. 10A is a cross-sectional view of the second structure GS2 according to Embodiment 2, and FIG. 10B is a plan view of the second structure GS2 according to Embodiment 2. Embodiment 2 is an embodiment where the second structure GS2 according to the display device 700 of FIG. 7 is provided.

Comparative Embodiments, Embodiment 1, and Embodiment 2 illustrated in FIGS. 8A, 9A, and 10A each illustrate a state before the encapsulation substrate 140 and the substrate 110 are bonded, and illustrate the second structure GS2 in the state before the encapsulation substrate 140 is overturned.

Referring to FIGS. 8A, 9A, and 10A, each of Comparative Embodiments, Embodiment 1, and Embodiment 2 includes a first pattern P1, a second pattern P2, a third pattern P3, and a fourth pattern P4.

The fourth pattern P4 is disposed on a bottom layer, and the first pattern P1, the second pattern P2, and the third pattern P3 are sequentially disposed over the fourth pattern P4. In Comparative Embodiments and Embodiments 1 and 2, the cross-sectional shapes of the fourth pattern P4, the first pattern P1, the second pattern P2, and the third pattern P3 were assumed to be squares with the same breadth and width, respectively. In addition, in Comparative Embodiment and Embodiments 1 and 2, respectively, the process margin forming the fourth pattern P4, the first pattern P1, the second pattern P2, and the third pattern P3 were assumed to be about 14 μm.

The width of each pattern according to Comparative Embodiments and Embodiments 1 and 2 and the total area of Comparative Embodiments and Embodiments 1 and 2 are summarized in Table 1. In Table 1, the total area refers to the cross-sectional area of each of Comparative Embodiments, Embodiment 1, and Embodiment 2. Accordingly, in Comparative Embodiments, Embodiments 1 and 2, respectively, the total area is equal to the area of the pattern with the maximum width among the plurality of patterns constituting the Comparative Embodiments and Embodiments 1 and 2.

TABLE 1

| | Comparative | | | | | |
|---|---|---|---|---|---|---|
| | Embodiment | | Embodiment 1 | | Embodiment 2 | |
| Third Pattern | 14 | μm | 14 | μm | 28 | μm |
| Second Pattern | 28 | μm | 28 | μm | 14 | μm |
| First Pattern | 42 | μm | 14 | μm | 28 | μm |
| Fourth Pattern | 56 | μm | 28 | μm | 42 | μm |
| Total Area | 3136 | μm² | 784 | μm² | 1764 | μm² |

Referring to FIG. 8A, in Comparative Embodiment, the width of the fourth pattern P4, the width of the first pattern P1, the width of the second pattern P2, and the width of the third pattern P3 each decrease in order of about 56 μm, 42 μm, 28 μm, and 14 μm.

Referring to FIG. 8B and Table 1, it can be seen that in Comparative Embodiment, the total area is the same as the area of the fourth pattern P4 and is about 3136 μm².

Referring to FIG. 9A, in Embodiment 1, the width of the fourth pattern P4 and the width of the second pattern P2 are the same at about 28 μm, and the width of the first pattern P1 and the width of the third pattern P3 are the same at about 14 μm.

Referring to FIG. 9B and Table 1, it can be seen that in Embodiment 1, the total area is the same as the area of the fourth pattern P4 and the area of the second pattern P2 and is about 784 μm².

Referring to FIG. 10A, in Embodiment 2, the width of the fourth pattern P4, the width of the first pattern P1, and the width of the second pattern P2 each decrease in the order of about 42 μm, 28 μm, and 14 μm. The width of the third pattern P3 is the same as the width of the first pattern P1 as about 28 μm.

Referring to FIG. 10B and Table 1, it can be seen that in Embodiment 2, the total area is the same as the area of the fourth pattern P4 and is about 1764 μm².

Accordingly, it can be seen that the total area in each of Embodiments 1 and 2 corresponds to about 25% and 56% of the total area of Comparative Embodiment, and the total area in each of Embodiments 1 and 2 decreases by about 75% and 44% of the total area of Comparative Embodiment.

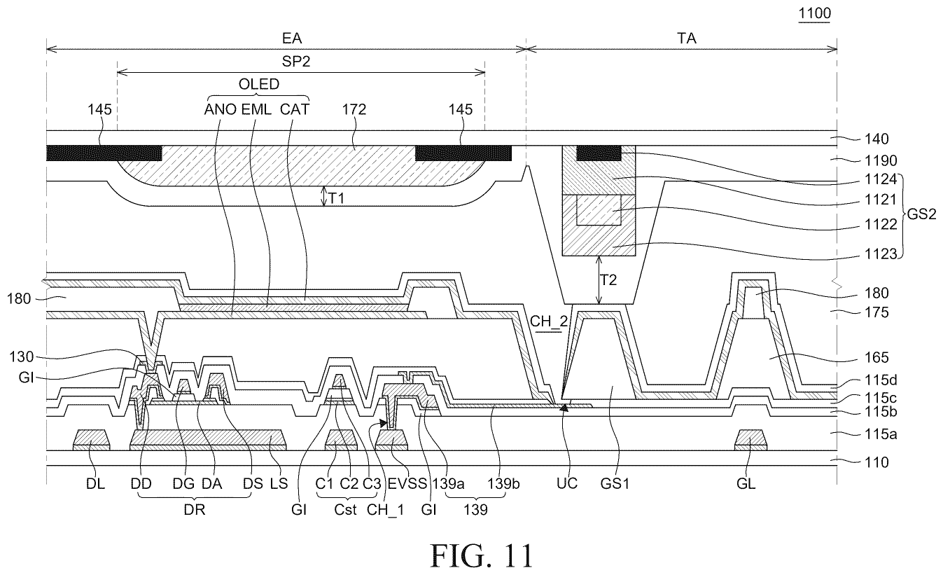

FIG. 11 is a cross-sectional view of the display device according to still another embodiment of the present disclosure.

A display device 1100 of FIG. 11 is different from the display device 100 of FIGS. 1 to 5 only in the second structure GS2 and an insulating layer 1190, and other components are substantially the same, and therefore, redundant descriptions thereof will be omitted. The same reference numerals will be used for the same components. Hereinafter, descriptions of the same reference numerals may refer to FIGS. 1 to 5.

Referring to FIG. 11, the second structure GS2 may be disposed in the transmissive area TA.

For example, the second structure GS2 may include a first pattern 1121, a second pattern 1122, a third pattern 1123, and a fourth pattern 1124 disposed below the encapsulation substrate 140.

The fourth pattern 1124 may be disposed below the encapsulation substrate 140, and the first pattern 1121 may be disposed below the fourth pattern 1124.

The overlapping area of the first pattern 1121 with the encapsulation substrate 140 may be larger than the overlapping area of the fourth pattern 1124 with the encapsulation substrate 140. Accordingly, the first pattern 1121 may be disposed to surround the side surface of the fourth pattern 1124. Meanwhile, the difference between the width of the first pattern 1121 and the width of the fourth pattern 1124 may correspond to the process margin, but is not limited thereto.

The second pattern 1122 may be disposed below the first pattern 1121.

The overlapping area of the second pattern 1122 with the encapsulation substrate 140 may be smaller than the overlapping area of the first pattern 1121 with the encapsulation substrate 140.

Meanwhile, the difference between the width of the first pattern 1121 and the width of the second pattern 1122 may correspond to the process margin, and the second pattern 1122 may have the same width as the fourth pattern 1124, and is not limited thereto.

The third pattern 1123 may be disposed below the second pattern 1122.

The overlapping area of the third pattern 1123 with the encapsulation substrate 140 may be larger than the overlapping area of the second pattern 1122 with the encapsulation substrate 140. Accordingly, the third pattern 1123 may be disposed to surround the side surface of the second pattern 1122. In this case, the width of the first pattern 1121 and the width of the third pattern 1123 may be larger than the width of the second pattern 1122. Therefore, the third pattern 1123 and the first pattern 1121 may be disposed to contact each other on an outside of the second pattern 1122, and the first pattern 1121 and the third pattern 1123 may be disposed to enclose the second pattern 1122. Meanwhile, the difference between the width of the second pattern 1122 and the width of the third pattern 1123 may correspond to the process margin, and the third pattern 1123 may have the same width as the first pattern 1121, and is not limited thereto.

An insulating layer 1190 may be disposed below the encapsulation substrate 140 including the color filter 170. The insulating layer 1190 may be disposed between the first structure GS1 and the second structure GS2 in the transmissive area TA.

In the display device 1100 according to still another embodiment of the present disclosure, the first structure GS1 may be formed above the end of the cathode connection line 139, and the second structure GS2 may be formed below the encapsulation substrate 140 facing the first structure GS1, thereby uniformly maintaining the cell gap. As a result, it is possible to improve the pressing dark spots caused by internal foreign objects.

In addition, in the display device 1100 according to still another embodiment of the present disclosure, the insulating layer 1190 may have different thicknesses in the transmissive area TA and the emission area EA. For example, by increasing the thickness of the insulating layer 1190 in the transmissive area TA, it is possible to uniformly maintain the cell gap and improve the pressing dark spots caused by internal foreign objects.

In the display device 1100 according to still another embodiment of the present disclosure, for example, the first pattern 1121 having a larger area than the fourth pattern 1124 is disposed below the fourth pattern 1124 so that the first pattern 1121 is disposed to surround the fourth pattern 1124. In addition, the second pattern 1122 having a smaller area than the first pattern 1121 is disposed below the first pattern 1121. Therefore, even if the number of patterns constituting the second structure GS2 increases, the total area of the second structure GS2 may be kept constant and the problem of decreasing the aperture ratio of the transmissive area TA may be improved.

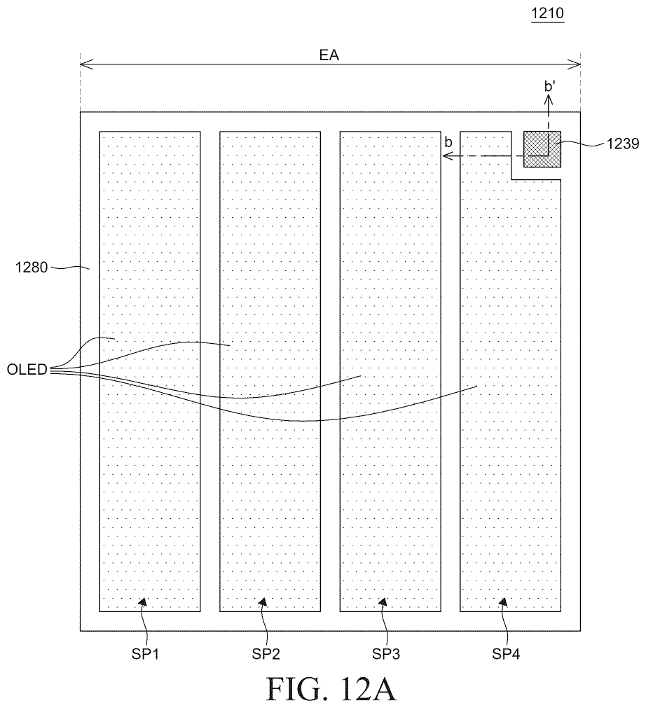

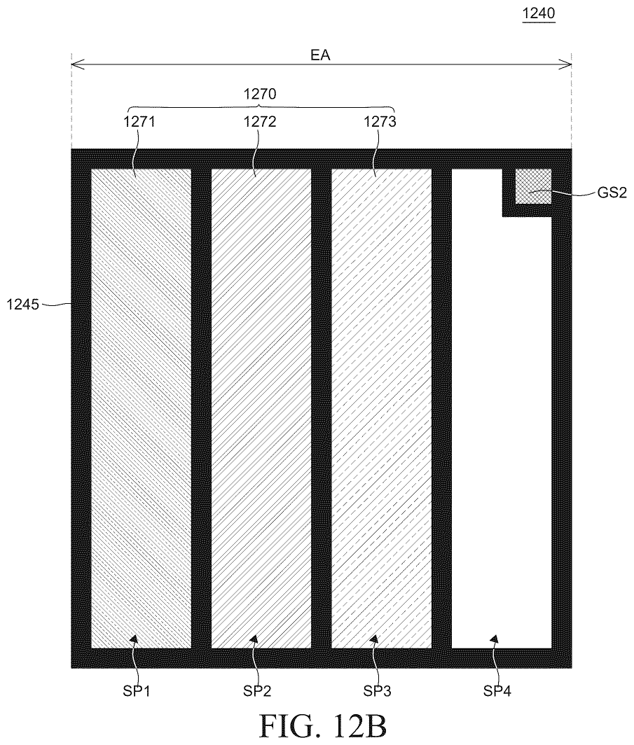

FIG. 12A is a schematic plan view of a substrate for a pixel area of the display device according to still another embodiment of the present disclosure.

FIG. 12B is a schematic plan view of an encapsulation substrate for the pixel area of the display device according to still another embodiment of the present disclosure.

Referring to FIGS. 12A and 12B, an emission area EA of a display device 1200 may include a first sub-pixel SP1, a second sub-pixel SP2, a third sub-pixel SP3, and a fourth sub-pixel SP4.

In this case, the organic light emitting diode OLED is disposed in the emission area EA on the substrate 110, and each of the first sub-pixel SP1, the second sub-pixel SP2, the third sub-pixel SP3, and the fourth sub-pixel SP4 may be partitioned by a bank layer 1280.

In addition, a cathode connection line 1239 may be disposed in the emission area EA on the substrate 1210. For example, the cathode connection line 1239 may be disposed adjacent to the fourth sub-pixel SP4 and may be electrically connected to the second electrode of the organic light emitting diode OLED extending from the fourth sub-pixel SP4.

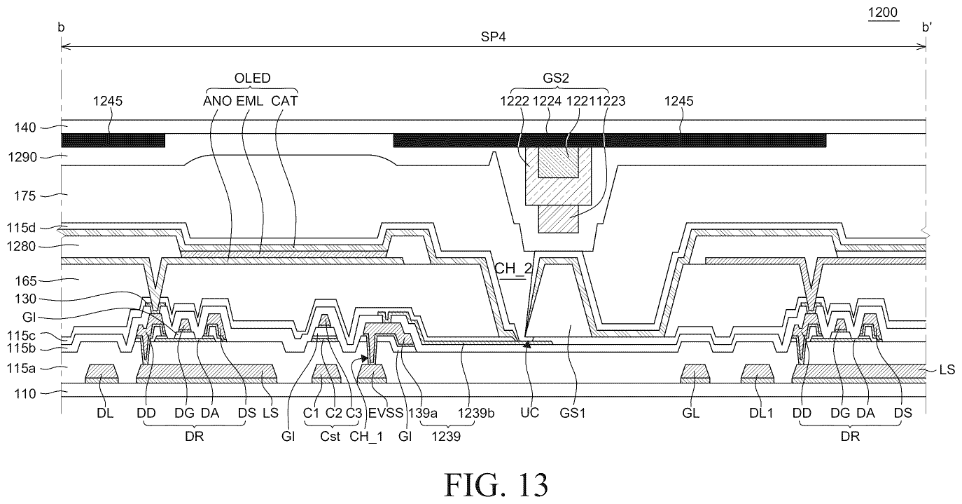

The electrical connection between the second electrode and the cathode connection line 1239 will be described in detail later with reference to FIG. 13.

In FIG. 12A, it is illustrated that the cathode connection line 1239 is disposed in an area adjacent to the fourth sub-pixel SP4 among the first to fourth sub-pixels SP1 to SP4. However, the present disclosure is not limited thereto, and the cathode connection line 1239 may be disposed in the area adjacent to one sub-pixel of the first to fourth sub-pixels SP1 to SP4.

In addition, a color filter 1270 may be disposed in the emission area EA on the encapsulation substrate 1240, and the color filter 1270 may be disposed to be surrounded by a black matrix 1245. For example, a first color filter layer 1271, a second color filter layer 1272, and a third color filter layer 1273 may be disposed in the first sub-pixel SP1, the second sub-pixel SP2, and the third sub-pixel SP3, respectively. Meanwhile, when the organic light emitting diode OLED emits white light and the fourth sub-pixel SP4 is a white sub-pixel, a separate color filter 1270 may not be disposed in the fourth sub-pixel SP4, but is not limited thereto.

In addition, the second structure GS2 may be disposed in the emission area EA. For example, the second structure GS2 may be disposed adjacent to the fourth sub-pixel SP4, and the second electrode of the organic light emitting diode OLED and the second power line EVSS may be electrically connected below the second structure GS2. The second structure GS2 may be positioned corresponding to the first structure GS1.

FIG. 13 is a cross-sectional view taken along line b-b′ of FIG. 12A according to still another embodiment of the present disclosure.

A display device 1200 of FIG. 13 is different from the display device 100 of FIGS. 1 to 5 only in the first structure GS1, the second structure GS2, the cathode connection line 1239, the bank layer 1280, the insulating layer 1290, and the black matrix 1245, and other components are substantially the same, and therefore, redundant descriptions thereof will be omitted. The same reference numerals will be used for the same components. Hereinafter, descriptions of the same reference numerals may refer to FIGS. 1 to 5.

The cathode connection line 1239 may be disposed over the substrate 110. For example, the cathode connection line 1239 may include a first cathode connection line 1239a and a second cathode connection line 1239b.

The second cathode connection line 1239b may be disposed over the first cathode connection line 1239a.

For example, the second cathode connection line 1239b may be electrically connected to the second electrode CAT in the emission area EA.

The first structure GS1 may be disposed above the end of the cathode connection line 1239b in emission area EA.

The undercut UC may be formed below the first structure GS1. For example, a portion of the top surface of the second cathode connection line 1239b may be exposed in the area overlapping the first structure GS1.

The organic light emitting diode OLED and the bank layer 1280 may be disposed over the substrate 110.

Some layers of the organic layer EML of the organic light emitting diode OLED and the second electrode CAT may be electrically connected to the top surface of the second cathode connection line 1239b exposed by the cathode contact hole CH_2 in the emission area EA.

In addition, the protective layer 115d, the adhesive film 175, and the encapsulation substrate 140 may be disposed over the organic light emitting diode OLED.

The second structure GS2 may be disposed below the encapsulation substrate 140 to overlap the first structure GS1.

The second structure GS2 may be disposed in the emission area EA.

The second structure GS2 may include the first pattern 1221, the second pattern 1222, the third pattern 1223, and the fourth pattern 1224 disposed below the encapsulation substrate 140.

The fourth pattern 1224 may be disposed below the encapsulation substrate 140, and the first pattern 1221 may be disposed below the fourth pattern 1224. The fourth pattern 1224 may be connected to the black matrix 1245, but is not limited thereto.

The overlapping area of the first pattern 1221 with the encapsulation substrate 140 may be smaller than the overlapping area of the fourth pattern 1224 with the encapsulation substrate 140.

The second pattern 1222 may be disposed below the first pattern 1221. The overlapping area of the second pattern 1222 with the encapsulation substrate 140 may be larger than the overlapping area of the first pattern 1221 with the encapsulation substrate 140. Accordingly, the second pattern 1222 may be disposed to surround the side surface of the first pattern 1221.

The third pattern 1223 may be disposed below the second pattern 1222.

The overlapping area of the third pattern 1223 with the encapsulation substrate 140 may be smaller than the overlapping area of the second pattern 1222 with the encapsulation substrate 140.

The insulating layer 1290 may be disposed below the encapsulation substrate 140 including the color filter 1270. The insulating layer 1290 may be disposed between the first structure GS1 and the second structure GS2 in the emission area EA.

Meanwhile, the insulating layers 1290 may all be disposed to have the same thickness, but are not limited thereto.

In the display device 1200 according to still another embodiment of the present disclosure, the first structure GS1 may be formed above the end of the cathode connection line 1239, and the second structure GS2 may be formed below the encapsulation substrate 140 facing the first structure GS1, thereby uniformly maintaining the cell gap. As a result, it is possible to improve the pressing dark spots caused by internal foreign objects.

In the display device 1200 according to still another embodiment of the present disclosure, the fourth pattern 1224, the first pattern 1221, the second pattern 1222, and the third pattern 1223 may be disposed below the encapsulation substrate 140, and the second pattern 1222 may be disposed to surround the side surface of the first pattern 1221. In addition, the third pattern 1223 having a smaller area than the second pattern 1222 may be disposed below the second pattern 1222. Therefore, even if the number of patterns constituting the second structure GS2 increases, the total area of the second structure GS2 may be kept constant and the problem of decreasing the aperture ratio of the emission area EA may be improved.

The embodiments of the present disclosure can also be described as follows:

According to one or more embodiments of the present disclosure, there is provided a display device. The display device includes a substrate on which a plurality of sub-pixels may be defined, a first structure disposed over the substrate, an encapsulation substrate disposed over the substrate and a second structure disposed below the encapsulation substrate, facing the first structure, the second structure may include a plurality of stacked patterns, and a second pattern of the plurality of patterns may surround a side surface of a first pattern of the plurality of stacked patterns, the second pattern below the first pattern.

The second structure may further include a third pattern disposed below the second pattern.

A width of the first pattern and a width of the third pattern may be the same.

The display device may further comprise a first color filter layer, a second color filter layer, and a third color filter layer disposed in each of the plurality of sub-pixels, the first pattern may be formed of the same material as the first color filter layer, the second pattern may be formed of the same material as the second color filter layer, and the third pattern may be formed of the same material as the third color filter layer.

A width of the first pattern and a width of the third pattern may be smaller than a width of the second pattern.

The second pattern may be disposed to surround a side surface of the first pattern.

A width of the first pattern and a width of the third pattern may be larger than a width of the second pattern.

The third pattern and the first pattern may contact each other outside the second pattern.

The first pattern and the third pattern may be disposed to surround the second pattern.

The display device may further comprise a black matrix disposed on one side surface of the encapsulation substrate, the second structure may be formed of the same material as the black matrix and may further include a fourth pattern disposed between the encapsulation substrate and the first pattern.

The first pattern may surround a side surface of the fourth pattern.

A width of the fourth pattern may be equal to or larger than a largest one of widths of the first, second, and third patterns.

A width of the fourth pattern may be equal to a width of the second pattern, and larger than a width the first pattern and a width of the third pattern.

The display device may further comprise organic light emitting diodes disposed in each of the plurality of sub-pixels, the first structure may include a first organic pattern, an undercut may be formed below the first structure, and a second electrode of the organic light emitting diode and a second power line may be electrically connected below the undercut.

The first structure may further include a second organic pattern disposed on the first organic pattern.

The substrate may be divided into an emission area and a transmissive area, and the first structure and the second structure may be disposed in the transmissive area.

The display device may further comprise a first cathode connection line electrically connected to the second power line through a first contact hole in the emission area.

The first cathode connection line may be electrically connected to the second electrode through a second cathode connection line in the transmissive area.

The first structure and the second structure may be disposed in the plurality of sub-pixels.

The first structure and the second structure may be disposed adjacent to a white sub-pixel among the plurality of sub-pixels.

The first structure may be disposed in an island shape.

Although the embodiments of the present disclosure have been described in detail with reference to the accompanying drawings, the present disclosure is not limited thereto and may be embodied in many different forms without departing from the technical concept of the present disclosure. Therefore, the embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate with a plurality of sub-pixels on the substrate;
a first structure over the substrate;
an encapsulation substrate over the substrate; and
a second structure below the encapsulation substrate, the second structure facing the first structure,
wherein the second structure includes a plurality of stacked patterns, and
wherein a second pattern of the plurality of stacked patterns surrounds a side surface of a first pattern of the plurality of stacked patterns, the second pattern below the first pattern.

2. The display device of claim 1, wherein the second structure further includes a third pattern below the second pattern.

3. The display device of claim 2, wherein a width of the first pattern and a width of the third pattern are same.

4. The display device of claim 2, further comprising:
a first color filter layer, a second color filter layer, and a third color filter layer in each of the plurality of sub-pixels,
wherein the first pattern includes a same material as the first color filter layer, the second pattern includes a same material as the second color filter layer, and the third pattern includes a same material as the third color filter layer.

5. The display device of claim 2, wherein each of a width of the first pattern and a width of the third pattern is smaller than a width of the second pattern.

6. The display device of claim 5, wherein the second pattern surrounds a side surface of the first pattern.

7. The display device of claim 2, wherein each of a width of the first pattern and a width of the third pattern is larger than a width of the second pattern.

8. The display device of claim 7, wherein the third pattern and the first pattern contact each other outside the second pattern.

9. The display device of claim 7, wherein the first pattern and the third pattern enclose the second pattern.

10. The display device of claim 2, further comprising:
a black matrix on a side surface of the encapsulation substrate,
wherein the second structure includes a same material as the black matrix, and the second structure further includes a fourth pattern between the encapsulation substrate and the first pattern.

11. The display device of claim 10, wherein the first pattern surrounds a side surface of the fourth pattern.

12. The display device of claim 10, wherein a width of the fourth pattern is equal to or larger than a largest one of a width of the first pattern, a width of the second pattern, and a width of the third pattern.

13. The display device of claim 10, wherein a width of the fourth pattern is equal to a width of the second pattern, and the width of the fourth pattern is larger than a width of the first pattern and a width of the third pattern.

14. The display device of claim 1, further comprising:
a plurality of organic light emitting diodes in each of the plurality of sub-pixels,
wherein the first structure includes a first organic pattern,
wherein an undercut is below the first structure, and
an electrode of the plurality of organic light emitting diodes and a power line are electrically connected below the undercut.

15. The display device of claim 14, wherein the first structure further includes a second organic pattern on the first organic pattern.

16. The display device of claim 14, wherein the substrate on which the plurality of sub-pixels are defined is divided into an emission area and a transmissive area, and wherein the first structure and the second structure are disposed in the transmissive area.

17. The display device of claim 16, further comprising:
a first cathode connection line electrically connected to the power line through a contact hole in the emission area.

18. The display device of claim 17, wherein the first cathode connection line is electrically connected to the electrode through a second cathode connection line in the transmissive area.

19. The display device of claim 14, wherein the first structure and the second structure are in the plurality of sub-pixels.

20. The display device of claim 19, wherein the first structure and the second structure are adjacent to a white sub-pixel of the plurality of sub-pixels.

21. The display device of claim 1, wherein the first structure has an island shape.
